(19) United States
(12) Patent Application Publication
(10) Pub. No.: US 2022/0355664 A1
(43) Pub. Date: Nov. 10, 2022

(54) VEHICLE HAVING VOICE RECOGNITION SYSTEM AND METHOD OF CONTROLLING THE SAME

(71) Applicants: Hyundai Motor Company, Seoul (KR); Kia Corporation, Seoul (KR)

(72) Inventors: Sungwang Kim, Seoul (KR); Woo Taek Lim, Gimpo (KR); Minjae Park, Seongnam (KR); Donghyeon Lee, Suwon (KR)

(21) Appl. No.: 17/670,887

(22) Filed: Feb. 14, 2022

(30) Foreign Application Priority Data
May 4, 2021 (KR) 10-2021-0057871

(51) Int. Cl. B60K 35/00; B60R 16/037; G10L 15/22; H04R 1/02

(52) U.S. Cl. CPC B60K 35/00; B60R 16/0373; G10L 15/22; H04R 1/02; B60K 2370/143; B60K 2370/148; G10L 2015/223; H04R 2499/13

(57) ABSTRACT

A vehicle includes a plurality of tactile input devices configured to receive a tactile input for controlling a function of the vehicle; a microphone configured to receive an audio input; and a voice recognition system configured to control the function of the vehicle based on the audio input, where the voice recognition system is configured to determine a target object to be controlled based on the tactile input, determine a control instruction for the target object based on the audio input, and control the target object based on the control instruction.

### CROSS-REFERENCE TO RELATED APPLICATION(S)

This application is based on and claims priority under 35 U.S.C. § 119 to Korean Patent Application No. 10-2021-0057871, filed on May 04, 2021 in the Korean Intellectual Property Office, the disclosure of which is incorporated herein by reference in its entirety.

### BACKGROUND

### (a) Technical Field

The disclosure relates to a vehicle having a voice recognition system and a method of controlling the same, more particularly, to the vehicle and control method capable of conveniently controlling various functions of the vehicle.

### (b) Description of the Related Art

A voice recognition system is a system capable of recognizing a user's utterance and providing services corresponding to the recognized utterance.

Recently, various types of services with respect to a voice recognition system of a vehicle have been provided, and in particular, when an occupant inside the vehicle utters a command for controlling one or more functions of the vehicle, the one or more functions of the vehicle may be controlled according to an intention of the occupant.

In particular, the occupant may control various functions of the vehicle through an utterance command including a target object to be controlled and a control command for the target object.

Furthermore, the occupant needs to activate a voice recognition system by using a call word before the utterance command.

However, the longer occupant's utterance command becomes, typically the lower accuracy of recognition of the utterance command by the voice recognition system of the vehicle.

### SUMMARY

The disclosure provides a vehicle having a voice recognition system capable of conveniently controlling various functions of the vehicle based on a combination of an audio input and a tactile input, and a method of controlling the same.

Additional aspects of the disclosure will be set forth in part in the description which follows and, in part, will be obvious from the description, or may be learned by practice of the disclosure.

In accordance with an aspect of the disclosure, a vehicle includes a plurality of tactile input devices configured to receive a tactile input for controlling a function of the vehicle; a microphone configured to receive an audio input; and a voice recognition system configured to control the function of the vehicle based on the audio input; wherein the voice recognition system is configured to determine a target object based on the tactile input, determine a control instruction for the target object based on the audio input, and control the target object based on the control instruction.

The voice recognition system may be activated in response to receiving the tactile input.

The voice recognition system may determine the target object as a first function in response to receiving a first tactile input for controlling the first function of the vehicle.

The voice recognition system may determine the target object as a second function in response to receiving a second tactile input for controlling the second function of the vehicle.

The voice recognition system may identify the audio input received through the microphone in a state in which the first tactile input is being received as an utterance command for controlling the first function.

The voice recognition system may recognize a user's voice and determine the target object as a first function in response to receiving a first tactile input for controlling the first function of the vehicle even if the user's voice includes a command for specifying the target object as a second function of the vehicle.

The voice recognition system may recognize a user's voice and determine the target object based on the tactile input only when the user's voice does not include a command for specifying the target object.

The plurality of tactile input devices may include any one of a push button, a button for inputting a direction (e.g. joystick), or a touch pad for receiving a touch input.

The plurality of tactile input devices may include a first tactile input device configured to receive a first tactile input for controlling a first function of the vehicle; and a second tactile input device configured to receive a second tactile input for controlling a second function of the vehicle.

The tactile input for controlling the function of the vehicle may be for turning on/off the function of the vehicle or setting the function of the vehicle.

In accordance with another aspect of the disclosure, a method of controlling a vehicle, the method includes receiving a tactile input for controlling a function of the vehicle; receiving an audio input; determining an target object based on the tactile input; determining a control instruction for the target object based on the audio input; and controlling the target object based on the control instruction.

The step of determining the control instruction may be performed in response to receiving the tactile input.

The step of determining the target object may include determining the target object as a first function in response to receiving a first tactile input for controlling the first function of the vehicle.

The step of determining the target object may include determining the target object as a second function in response to receiving a second tactile input for controlling the second function of the vehicle.

The step of determining the control instruction may include identifying the audio input received in a state in which the first tactile input is being received as an utterance command for controlling the first function.

The method may further include a step of recognizing a user's voice based on the audio input; wherein the step of determining the target object may further include determining the target object as a first function in response to receiving a first tactile input for controlling the first function of the vehicle even if the user's voice includes a command for specifying the target object as a second function of the vehicle.

The method may further include a step of recognizing a user's voice based on the audio input; wherein the step of determining the target object based on the tactile input is performed only when the user's voice does not include a command for specifying the target object.

The step of receiving the tactile input may be performed by any one of a push button, a button for inputting direction (e.g. joystick), or a touch pad for receiving a touch input.

The step of receiving the tactile input may be performed by a first tactile input device configured to receive a first tactile input for controlling a first function of the vehicle; and a second tactile input device configured to receive a second tactile input for controlling a second function of the vehicle.

The tactile input for controlling the function of the vehicle may be for turning on/off the function of the vehicle or setting the function of the vehicle.

### BRIEF DESCRIPTION OF THE DRAWINGS

These and/or other aspects of the disclosure will become apparent and more readily appreciated from the following description of the exemplary embodiments, taken in conjunction with the accompanying drawings, of which:

FIG. 1 is a control block view of a vehicle according to an exemplary embodiment of the disclosure;

FIG. 2 is a partially view illustrating an internal configuration of the vehicle according to the exemplary embodiment of the disclosure;

FIG. 3 is a flowchart illustrating a method for controlling the vehicle according to the exemplary embodiment of the disclosure; and

FIGS. 4 to 8 are views illustrating a state in which a user controls a function of the vehicle according to various embodiments of the disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles. The terminology used herein is for the purpose of describing particular embodiments only and is not intended to be limiting of the disclosure.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Like numerals refer to like elements throughout the specification. Not all elements of embodiments of the disclosure will be described, and description of what are commonly known in the art or what overlap each other in the embodiments will be omitted.

It will be further understood that the term “connect” or its derivatives refer both to direct and indirect connection, and the indirect connection includes a connection over a wireless communication network.

Further, when it is stated that a member is “on” another member, the member may be directly on the other member or a third member may be disposed therebetween.

Although the terms “first,” “second,” “A,” “B,” etc. may be used to describe various components, the terms do not limit the corresponding components, but are used only for the purpose of distinguishing one component from another component.

Reference numerals used for method steps are just used for convenience of explanation, but not to limit an order of the steps. Thus, unless the context clearly dictates otherwise, the written order may be practiced otherwise.

Hereinafter, operating principles and embodiments of the disclosure will be described with reference to the accompanying drawings.

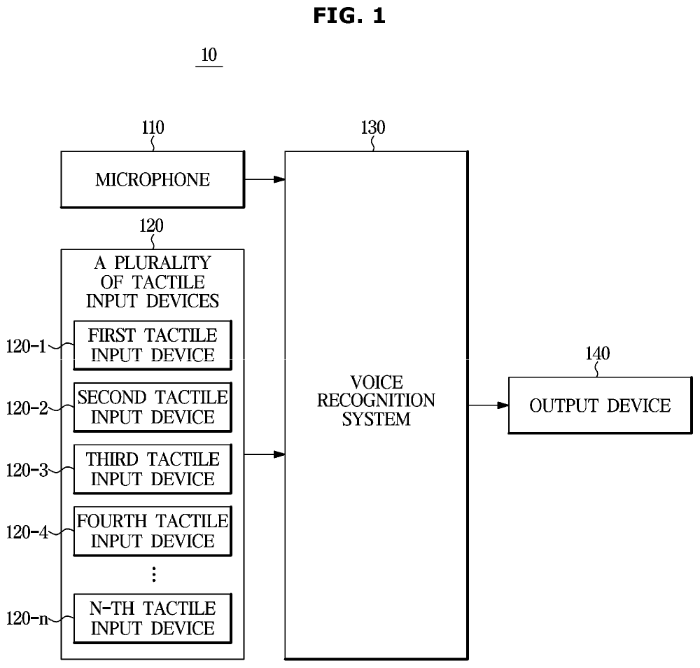

FIG. 1 is a control block view of a vehicle according to an exemplary embodiment of the disclosure.

Referring to FIG. 1, a vehicle 10 according to the exemplary embodiment may include a microphone 110, a plurality of tactile input devices 120, a voice recognition system 130, and an output device 140.

The microphone 110 may receive an audio input and generate an electrical signal corresponding to the audio input.

The microphone 110 may be installed inside the vehicle 10 in order to receive a user's voice in the vehicle 10, may be provided as a plurality of microphones, and may be provided in the form of an array.

The microphone 110 may convert a user's audio input (e.g., voice) into an electrical signal to transmit to the voice recognition system 130.

The plurality of tactile input devices 120 may receive a tactile input for controlling various functions of the vehicle 10.

The tactile input may refer to an input by a user's physical manipulation (e.g., push, drag, or touch).

For the user's physical manipulation, the plurality of tactile input devices 120 may include at least one of a button for inputting direction (e.g. joystick) provided to be movable up, down, left and right according to a direction of externally applied force, a push button provided to be pushed by externally applied force, and a touch pad for receiving a touch input.

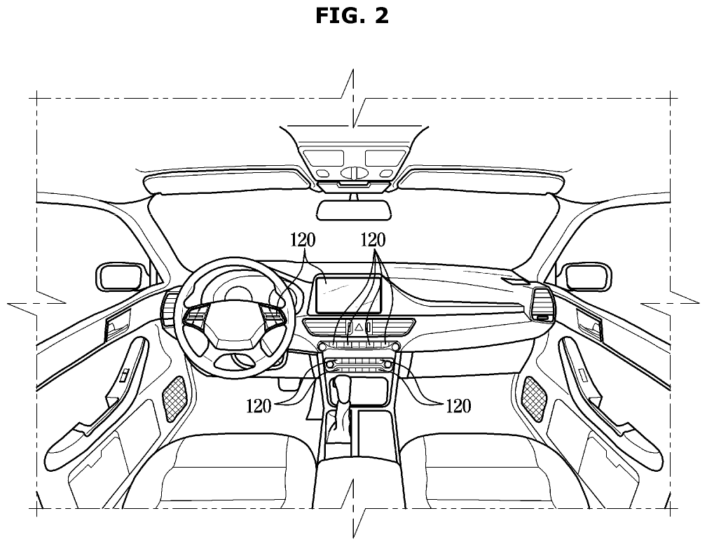

FIG. 2 is a view illustrating a part of an internal configuration of the vehicle according to the exemplary embodiment.

Referring to FIG. 2, it may be seen that a variety of tactile input devices 120 are disposed inside the vehicle 10.

Each of the plurality of tactile input devices 120 may receive a tactile input for controlling a specific function provided by the vehicle 10.

Various functions provided by the vehicle 10 according to the exemplary embodiment may include any one of an air conditioning control function, a door control function, a window control function, a multimedia control function, a seat control function, a sunroof control function, a lighting control function, a navigation control function, a radio control function, an autonomous driving control function (e.g., a cruise control function), and other vehicle-related setting control functions. However, the listed functions of the vehicle 10 are merely examples, and other functions may be included in addition to the examples.

In an exemplary embodiment, the plurality of tactile input devices 120 may include a first tactile input device 120-1 (e.g., the push button) that receives a first tactile input (e.g., a push input) for controlling a first function (e.g., a ventilated seat function) of the vehicle 10, a second tactile input device 120-2 (e.g., the push button) that receives a second tactile input (e.g., a push input) for controlling a second function (e.g., the air conditioning control function) of the vehicle 10, a third tactile input device 120-3 (e.g., the push button) that receives a third tactile input (e.g., a movement input) for controlling a third function (e.g., the cruise control function) of the vehicle 10, a fourth tactile input 120-4 (e.g., the push button or the touch pad) that receives a fourth tactile input (e.g., a push input or touch input) for controlling a fourth function (e.g., the radio control function) of the vehicle 10, and an n-th tactile input device 120-n (e.g., the touch pad) that receives a n-th function (e.g., a touch input) for controlling an n-th function (e.g., the sunroof control function) of the vehicle 10.

As such, each of the plurality of tactile input devices 120 may be independently provided to control corresponding functions, and may be implemented in various forms.

The voice recognition system 130 may control a function of the vehicle 10 based on a combination of the tactile input and the audio input.

In an exemplary embodiment, the voice recognition system 130 may determine an object to be controlled (target object) based on the tactile input, determine a control instruction for an object to be controlled based on the audio input, and determine the object to be controlled based on the control instruction.

In other words, the voice recognition system 130 may determine the object to be controlled based on the tactile input received through any one of the plurality of tactile input devices 120 (e.g., the first tactile input device 120-1), and then determine how to control the object to be controlled based on the received audio input.

The voice recognition system 130 may include a program for performing the above-described operation and an operation to be described later, at least one memory in which a variety of data necessary for executing the program are stored, and at least one processor executing the stored program.

When a plurality of memories and processors included in the voice recognition system 130 are provided, they may be integrated on one chip or physically separated.

In an exemplary embodiment, the voice recognition system 130 may include a voice processor for processing the audio input (e.g., an utterance command).

The voice processor may include a speech to text (STT) engine that converts a user's audio input (e.g., an utterance command) input through the microphone 110 into text information, and a dialog manager that analyzes the text to identify a user's intention included in the utterance command.

The dialog manager may apply a natural language understanding technology to the text to identify the user's intention corresponding to the utterance command.

Specifically, the dialog manager converts an input string into a morpheme sequence by performing morpheme analysis on the utterance command in a text form. Furthermore, the dialog manager may identify a named entity from the utterance command. The named entity may be a proper noun such as a person's name, a place name, an organization name, a name representing a family, a name of various electrical devices of the vehicle 10, and the like. Recognition of the named entity refers to identify the named entity in a sentence and determine types of the named entity identified. The dialog manager may identify the meaning of the sentence by extracting important keywords from the sentence by recognizing the named entity.

Furthermore, the dialog manager may identify a domain from the user's utterance command. The domain may identify a subject of the language uttered by the user, and for example, the type of function, which is the object to be controlled, may be the domain. Accordingly, electronic device units inside the vehicle 10, such as a navigation device, a window driving unit, a ventilated seat driving unit, a radio unit, a sunroof driving unit, a cruise function control unit, an air conditioning function control unit, may be the domain.

Furthermore, the dialog manager may identify the control instruction from the user's utterance command. The control instruction may identify the purpose of the language uttered by the user, and may include the control instruction for the object to be controlled.

For example, the control instruction may include an ON/OFF command and a function setting command. The ON/OFF command is a command for activating or deactivating a specific function, and the function setting command may include a command for setting details of a specific function.

For example, the function setting command may include a command for opening the object to be controlled (e.g., a window), a command for changing a set temperature of the object to be controlled (e.g., an air conditioner) to a specific temperature, a command for changing a set speed of the object to be controlled (e.g., a cruise control function) to a specific speed, a command for changing a frequency of the object to be controlled (e.g., a radio) to a specific frequency, a command for changing levels of the object to be controlled (e.g., a ventilated seat function) to a specific level, a command for changing a mode of the object to be controlled (e.g., an air conditioner), and the like.

As such, the dialog manager may identify the user's intention based on information such as the domain, the named entity, and the control instruction corresponding to the user's utterance command, and extract an action corresponding to the user's intention.

For example, when the object to be controlled is ‘air conditioner’ and the control instruction is determined to be ‘execution’, the corresponding action may be defined as ‘air conditioner (object)_ON(operator)’, and when the object to be controlled is ‘window’ and the control instruction is determined to be ‘open’, the corresponding action may be defined as ‘window (object)_OPEN(operator)’.

The output device 140 may include various electronic devices capable of performing various functions of the vehicle 10. For example, the output device 140 may be the electronic devices inside the vehicle 10 such as a navigation device, a window driving unit, a ventilated seat driving unit, a radio unit, a sunroof driving unit, a cruise function control unit, an air conditioning function control unit, etc.

In an exemplary embodiment, the output device 140 may include an object to be controlled determined through the voice recognition system 130.

For example, when action data of ‘execute the air conditioner’ is extracted, the voice recognition system 130 may transmit a control signal for turning on the air conditioner to the output device 140 (e.g., the air conditioning function control unit).

According to the embodiments, the microphone 110, the plurality of tactile input devices 120, the voice recognition system 130, and the output device 140 may communicate via a vehicle communication network.

The vehicle communication network may employ communication methods such as an Ethernet, a Media Oriented Systems Transport (MOST), a Flexray, a Controller Area Network (CAN), and a Local Interconnect Network (LIN).

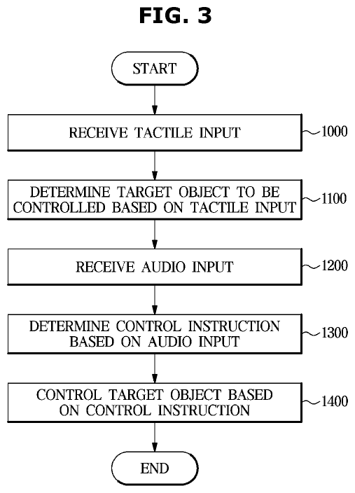

In an exemplary embodiment, when the plurality of tactile input devices 120 receive the tactile input, a communication message corresponding to the tactile input is transmitted directly or indirectly to another module (e.g., a body control module, the voice recognition system 130) connected through CAN communication. Various components of the vehicle 10 have been described above. Hereinafter, a method of controlling the vehicle 10 using the components of the vehicle 10 described above with reference to FIGS. 3 to 8 will be described.

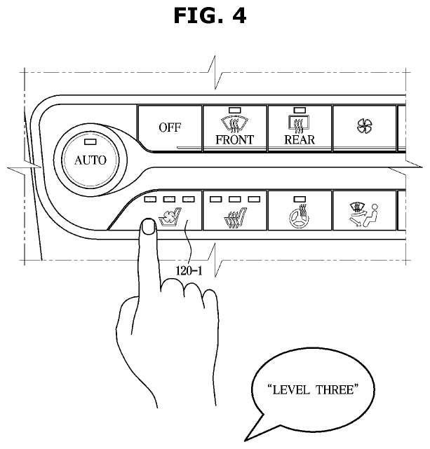

FIG. 3 is a flowchart of a method for controlling a vehicle according to an exemplary embodiment, and FIGS. 4 to 8 are views illustrating a state in which a user controls functions of a vehicle according to various exemplary embodiments.

The voice recognition system 130 may receive the user's utterance and determine the domain, the user's intention, and a slot, which correspond to the utterance. In this case, the slot may include a control amount for the object to be controlled.

In an exemplary embodiment, the voice recognition system 130 may determine at least one of the domain and the user's intention based on the tactile input received from the tactile input devices 120, and determine at least one of the user's intention and the slot based on the audio input (e.g., user's utterance).

In various embodiments, the voice recognition system 130 may determine the domain and the user's intention, the domain, or the user's intention according to the type of the tactile input devices 120 that have received the tactile input, and may determine an item that has not been determined by the tactile input based on the user's utterance.

In other words, the voice recognition system 130 according to the embodiment does not determine all of the domain, the user's intention, and the slot depending only on the user's utterance, but any one (e.g., the domain) of the domain, the user's intention, and the slot based on the user's physical manipulation. Accordingly, in the voice recognition system 130 according to the embodiment, the item determined based on the tactile input (e.g., the domain) and the item determined based on the audio input (e.g., the user's intention, the slot) may be different from each other.

For example, when the user presses the button of air conditioner and utters ‘turn on at 17 degrees’, in the voice recognition system 130 according to the embodiment, the domain may be determined as ‘air conditioner’ based on the user pressing the button of air conditioner and the user's intention may be determined as ‘turn on’ based on the user's utterance of ‘turn on at 17 degrees’ and the slot may be determined as ‘17 degrees’.

In another exemplary embodiment, when the user presses the radio button and utters ‘97.9’, in the voice recognition system 130 according to the embodiment, the domain may be determined as ‘radio’ based on the user pressing the radio button and the user's intention may be determined as ‘frequency control’ based on the utterance of ‘97.9’ and the slot may be determined as ‘97.9’.

In another exemplary embodiment, when the user presses the button of air volume and utters ‘up’, in the voice recognition system 130 according to the embodiment, the domain may be determined as ‘air volume control function’ based on the user pressing the button of air volume, and the user's intention may be determined as ‘air volume control’, and the slot may be determined as ‘upward’ based on the user's utterance of ‘up’.

Hereinafter, the above-described content will be described in more detail with reference to the drawings.

Referring to FIG. 3, any one of the plurality of tactile input devices 120 (e.g., the first tactile input device 120-1) may receive the tactile input according to the user's physical manipulation (1000).

For example, the first tactile input device 120-1 for controlling the first function of the vehicle 10 may receive the first tactile input.

The voice recognition system 130 may be activated in response to the tactile input device 120 receiving the tactile input.

Specifically, when the first tactile input device 120-1 for controlling the air conditioning function of the vehicle 10 receives the first tactile input, the communication message corresponding to the first tactile input is output through CAN communication, so that the voice recognition system 130 may receive the communication message corresponding to the first tactile input.

For example, the name of the communication message corresponding to the tactile input for controlling a set temperature of the air conditioner may be defined as ‘Air Temp’, and the communication message corresponding to the tactile input may include at least one signals containing user's intention. For example, the signal included in the communication message corresponding to the tactile input for controlling the set temperature of the air conditioner may include a first signal including an intention to lower the set temperature of the air conditioner and a second signal including an intention to raise the set temperature of the air conditioner. The name of the first signal may be defined as ‘Temp_Low’ and the name of the second signal may be defined as ‘Temp_High’.

In the exemplary embodiment, the voice recognition system 130 may be activated while the tactile input is being received through the tactile input device 120. In various embodiments, the voice recognition system 130 may be activated for a predetermined time (e.g., 2 seconds) after receiving the tactile input through the tactile input device 120.

For example, the voice recognition system 130 may be activated in response to receiving the communication message corresponding to the first tactile input via CAN communication.

In the exemplary embodiment, the user does not need to utter a call command for calling the voice recognition system 130, thereby promoting the user's convenience.

The voice recognition system 130 may determine the object to be controlled based on the tactile input in an activated state (1100). For example, the voice recognition system 130 may determine the object to be controlled as the first function in response to that the first tactile input device 120-1 receives the first tactile input for controlling the first function of the vehicle 10.

In an exemplary embodiment, the voice recognition system 130 may determine the object to be controlled based on text information included in the communication message received via the CAN communication.

For example, when the name of the communication message received via the CAN communication is defined as ‘Air Temp’, the voice recognition system 130 may determine the object to be controlled as the ‘air conditioner temperature setting function’. Likewise, the voice recognition system 130 may determine the object to be controlled as the second function in response to that the second tactile input device 120-2 receives the second tactile input for controlling the second function of the vehicle 10.

For example, when the name of the communication message received through the CAN communication is defined as ‘Sheet Fan’, the voice recognition system 130 may determine the object to be controlled as ‘ventilation seat function’.

To this end, the voice recognition system 130 may include a database for storing domain information corresponding to the name of the communication message or the name of the signals included in the communication message.

In an exemplary embodiment, even if the domain, in other words, the object to be controlled is not included in the user's utterance command, the voice recognition system 130 may determine the object to be controlled based on which type of tactile input devices 120 has received the tactile input.

According to an exemplary embodiment, because the user does not need to include the object to be controlled in the utterance command, the length of phrases included in the utterance command may be shortened, and accordingly, the voice recognition system 130 may more accurately identify the user's intention.

In an exemplary embodiment, the microphone 110 may receive the audio input (1200), and the voice recognition system 130 switched to an activated state by receiving the tactile input may determine the control instruction based on the audio input received through the microphone 110 (1300).

In other words, the voice recognition system 130 may recognize the audio input received through the microphone 110 as the utterance command for controlling the first function while the first tactile input is being received through the first tactile input device 120-1.

The voice recognition system 130 may determine a final action based on the object to be controlled determined from the tactile input and the control instruction determined from the audio input, and control the output device 140 in response to the determined final action (1400).

In an exemplary embodiment, the voice recognition system 130 may output the communication message corresponding to the final action determined through the CAN communication, and a module (e.g., a body control module (BCM)) corresponding to the final action may control the corresponding electrical components based on the communication message received through the CAN communication.

In other words, the voice recognition system 130 may control the object to be controlled determined based on the tactile input, based on the control instruction determined based on the audio input.

According to an embodiment, the user operates the tactile input devices related to the desired function to be controlled without calling the voice recognition system 130 and utters only the corresponding control command, so that various functions of the vehicle 10 may be controlled simply.

Referring to FIG. 4, the voice recognition system 130 may be activated in response to the user pushing the first tactile input device 120-1 (e.g., the push button related to the ventilated seat function), and the voice recognition system 130 may determine the object to be controlled as the ventilated seat function in response to uttering ‘level three’ while pushing the first tactile input device 120-1 and then determine the control instruction to ‘execution with level three’.

Accordingly, the voice recognition system 130 may determine the final action as ‘ventilated seat_ON_LEVEL 3’, and may control the output device 140 (e.g., the ventilation sheet control unit) based on the final action.

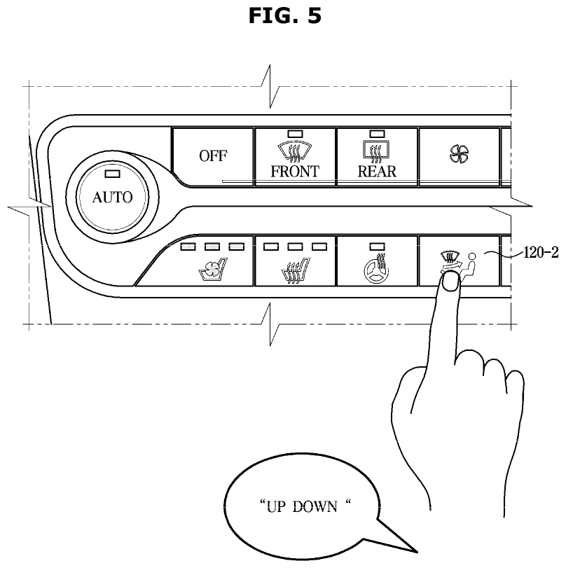

Referring to FIG. 5, the voice recognition system 130 may be activated in response to the user pushing the second tactile input device 120-2 (e.g., the push button related to a direction setting mode of the air conditioner), and the voice recognition system 130 may determine the object to be controlled as the air conditioning function in response to uttering ‘up, down’ while pushing the second tactile input device 120-2 and then determine the control instruction to ‘updown mode’.

Accordingly, the voice recognition system 130 may determine the final action as ‘air conditioner_MODE_UPDOWN’, and may control the output device 140 (e.g., the air conditioning function control unit) based on the final action.

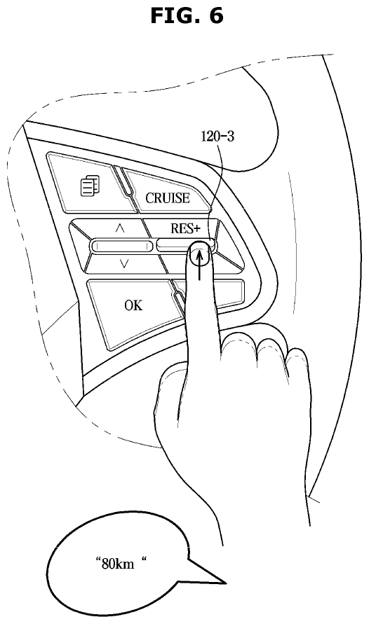

Referring to FIG. 6, the voice recognition system 130 may be activated in response to the user pushing the third tactile input device 120-3 (e.g., the joystick for speed setting of the cruise function) upward, and the voice recognition system 130 may determine the object to be controlled to be the cruise control function in response to the user uttering ‘80 km’ while pushing the third tactile input device 120-3 upward and then determine the control instruction to ‘setting to 80 km’.

Accordingly, the voice recognition system 130 may determine the final action as ‘cruise function_ON_80 km’, and may control the output device 140 (e.g., the cruise function control unit) based on the final action.

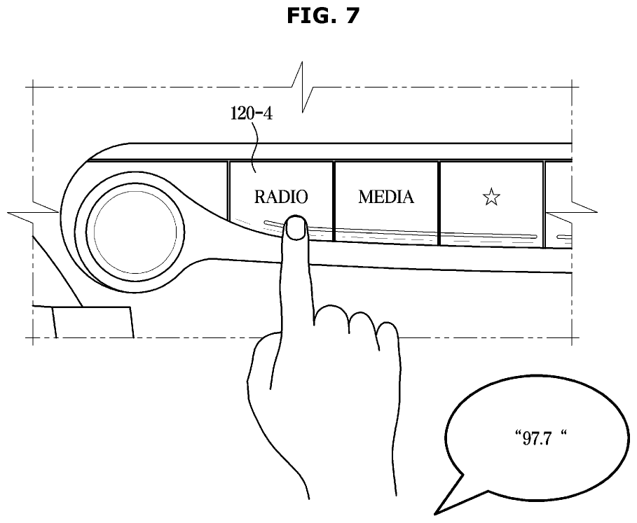

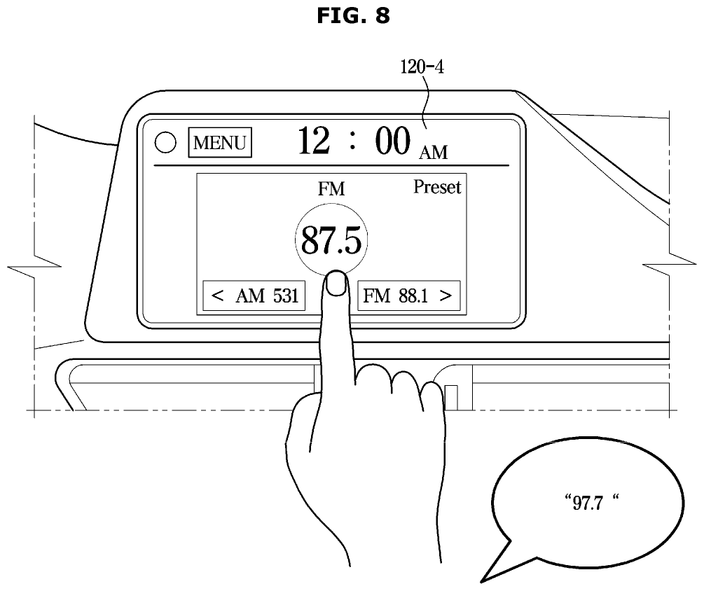

Referring to FIGS. 7 and 8, the voice recognition system 130 may be activated in response to the user pushing (or touching) the fourth tactile input device 120-4 (e.g., the push button or touch pad for setting the radio function), and the voice recognition system 130 may determine the object to be controlled to be the radio control function in response to the user uttering ‘97.7’ while pushing (or touching) the fourth tactile input device 120-4 and then determine the control instruction to ‘frequency to 97.7’.

Accordingly, the voice recognition system 130 may determine the final action as ‘radio function FREQUENCY 97.7’, and may control the output device 140 (e.g., a radio function control unit) based on the final action.

According to various embodiments, the user may set a priority for any one of the tactile input and the audio input.

According to various embodiments, when the priority is set to the tactile input, even if the voice recognition system 130 recognizes the user's voice based on the audio input and the user's voice includes the command for specifying the object to be controlled as the second function of the vehicle 10, the voice recognition system 130 may determine the object to be controlled as the first function in response to receiving the first tactile input for controlling the first function of the vehicle 10.

For example, when the user utters ‘turn on the air conditioner’ while pushing the tactile input device 120-4 related to the radio control function, the voice recognition system 130 may ignore the object to be controlled (the air conditioning control function) identified in the user's utterance command, and determine the object to be controlled as the radio control function.

According to an exemplary embodiment, even if the user erroneously utters the object to be controlled, the correct object to be controlled may be controlled.

According to various embodiments, when the priority is set to the audio input, the voice recognition system 130 may determine the object to be controlled based on the tactile input only if the user's voice does not include a command for specifying the object to be controlled.

For example, when the user utters ‘turn on the air conditioner’ while pushing the tactile input device 120-4 related to the radio control function, the voice recognition system 130 may determine the ‘air conditioner’ identified in the user's utterance command as the object to be controlled.

According to an embodiment, the user may utilize all tactile input devices inside the vehicle 10 as input devices for activating the voice recognition system 130.

In recent years, as the functions provided by vehicles have diversified, users often do not know the exact name of a specific function. Accordingly, when the user wants to control a specific function using the voice recognition function, detailed physical manipulation is inevitable.

According to an embodiment, the user only knows the location of the tactile input device for controlling a specific function and even if the user does not know exactly the name of the specific function, the user may easily control specific functions only by uttering while pressing, touching, or moving the specific tactile input devices.

Furthermore, in an exemplary embodiment, because the tactile input devices that require direct physical manipulation are used, the user's intention may be clearly identified.

As is apparent from the above, the embodiments of the disclosure may improve user convenience and usability of the voice recognition system by utilizing both the audio input and the tactile input.

Examples of the vehicle and its control method are not limited thereto, and the embodiments described above are exemplary in all respects. Therefore, those skilled in the art to which the present invention pertains will understand that the present invention can be implemented in other specific forms without changing the technical spirit or essential features thereof. The scope of the present invention is indicated by the claims rather than the foregoing description, and all differences within the scope equivalent thereto should be construed as being included in the present invention.

Meanwhile, the disclosed embodiments may be implemented in the form of a recording medium storing instructions executable by a computer. Instructions may be stored in the form of program code, and when executed by a processor, may generate program modules to perform operations of the disclosed embodiments. The recording medium may be implemented as a computer-readable recording medium.

The computer-readable recording medium includes all kinds of recording media in which instructions which can be decoded by a computer are stored, for example, a read only memory (ROM), a random access memory (RAM), a magnetic tape, a magnetic disk, a flash memory, an optical data storage device, and the like.

What is claimed is:

1. A vehicle, comprising:
a plurality of tactile input devices configured to receive a tactile input for controlling a function of the vehicle;
a microphone configured to receive an audio input; and
a voice recognition system configured to control the function of the vehicle based on the audio input;
wherein the voice recognition system is configured to determine a target object to be controlled based on the tactile input, determine a control instruction for the target object based on the audio input, and control the target object to be controlled based on the control instruction.

2. The vehicle of claim 1, wherein the voice recognition system is activated in response to receiving the tactile input.

3. The vehicle of claim 1, wherein the voice recognition system is configured to determine the target object as a first function in response to receiving a first tactile input for controlling the first function of the vehicle.

4. The vehicle of claim 3, wherein the voice recognition system is configured to determine the target object as a second function in response to receiving a second tactile input for controlling the second function of the vehicle.

5. The vehicle of claim 3, wherein the voice recognition system is configured to identify the audio input received through the microphone in a state in which the first tactile input is being received as an utterance command for controlling the first function.

6. The vehicle of claim 1, wherein the voice recognition system is configured to recognize a user's voice, and determine the target object as a first function in response to receiving a first tactile input for controlling the first function of the vehicle even if the user's voice includes a command for specifying the object to be controlled as a second function of the vehicle.

7. The vehicle of claim 1, wherein the voice recognition system is configured to recognize a user's voice, and determine the target object based on the tactile input only when the user's voice does not include a command for specifying the target object.

8. The vehicle of claim 1, wherein the plurality of tactile input devices comprise any one of a push button, a button for inputting direction, or a touch pad for receiving a touch input.

9. The vehicle of claim 1, wherein the plurality of tactile input devices comprises:
a first tactile input device configured to receive a first tactile input for controlling a first function of the vehicle; and
a second tactile input device configured to receive a second tactile input for controlling a second function of the vehicle.

10. The vehicle of claim 1, wherein the tactile input for controlling the function of the vehicle is for turning on/off the function of the vehicle or setting the function of the vehicle.

11. A method of controlling a vehicle, the method comprising the steps of:
receiving a tactile input for controlling a function of the vehicle;
receiving an audio input;
determining a target object to be controlled based on the tactile input;
determining a control instruction for the target object to be controlled based on the audio input; and
controlling the target object based on the control instruction.

12. The method of claim 11, wherein determining the control instruction is performed in response to receiving the tactile input.

13. The method of claim 11, wherein determining the target object comprises:
determining the target object as a first function in response to receiving a first tactile input for controlling the first function of the vehicle.

14. The method of claim 13, wherein determining the target object comprises:
determining the target object as a second function in response to receiving a second tactile input for controlling the second function of the vehicle.

15. The method of claim 13, wherein determining the control instruction comprises:
identifying the audio input received in a state in which the first tactile input is being received as an utterance command for controlling the first function.

16. The method of claim 11, further comprising recognizing a user's voice based on the audio input, wherein determining the target object further comprises:
determining the target object as a first function in response to receiving a first tactile input for controlling the first function of the vehicle even if the user's voice includes a command for specifying the target object as a second function of the vehicle.

17. The method of claim 11, further comprising recognizing a user's voice based on the audio input, wherein determining the target object based on the tactile input is performed only when the user's voice does not include a command for specifying the target object.

18. The method of claim 11, wherein receiving the tactile input is performed by any one of a push button, a button for inputting direction, or a touch pad for receiving a touch input.

19. The method of claim 11, wherein receiving the tactile input is performed by a first tactile input device configured to receive a first tactile input for controlling a first function of the vehicle and a second tactile input device configured to receive a second tactile input for controlling a second function of the vehicle.

20. The method of claim 11, wherein the tactile input for controlling the function of the vehicle is for turning on/off the function of the vehicle or setting the function of the vehicle.
